(19) United States
(12) Patent Application Publication
(10) Pub. No.: US 2015/0187976 A1
(43) Pub. Date: Jul. 2, 2015

(54) Composition of an Encapsulation Film for a Solar Cell Module

(71) Applicants: Chin-Zeng Yeh, Kaohsiung City (TW); Ming-Hung Chen, Kaohsiung City (TW); Jung-Chang Wang, Kaohsiung City (TW); Wei-Ju Chen, Pingtung City (TW); Min-Tsung Kuan, Taichung City (TW); Szu-Lin Wang, Baoshan Township (TW)

(72) Inventors: Chin-Zeng Yeh, Kaohsiung City (TW); Ming-Hung Chen, Kaohsiung City (TW); Jung-Chang Wang, Kaohsiung City (TW); Wei-Ju Chen, Pingtung City (TW); Min-Tsung Kuan, Taichung City (TW); Szu-Lin Wang, Baoshan Township (TW)

(21) Appl. No.: 14/146,070

(22) Filed: Jan. 2, 2014

(51) Int. Cl. H01L 31/048; C08L 53/00; C08L 31/04

(52) U.S. Cl. CPC H01L 31/0481; C08L 31/04; C08L 53/00; C08L 2201/08; C08L 2201/10; C08L 2203/204; C08L 2203/206

(57) ABSTRACT

A composition of an encapsulation film for a solar cell module comprises 80˜99 weight percent of transparent resin, 0.5˜10 weight percent of granular polymer particles and 0.1˜5 weight percent of additives, wherein light refraction is controlled by a diffusion mechanism of the granular polymer particles, so that the probability of light incidence on the solar cell is increased and thus the photoelectric conversion efficiency of the solar cell is improved.

### FIELD OF THE INVENTION

The present invention relates to a composition of an encapsulation film for a solar cell module, particularly to a composition of an encapsulation film for a solar cell module, wherein light refraction is controlled by a diffusion mechanism of the granular polymer particles, so that the probability of light incidence on the solar cell is increased and thus the photoelectric conversion efficiency of the solar cell is improved.

### BACKGROUND OF THE INVENTION

A solar cell is a system for converting sunlight to electricity. In the 1970s, people used transparent resin for encapsulating solar cell modules, to protect the latter from the influence of air and water vapor and thereby reduce failure rates thereof.

Common transparent resins are EVA-resin, PVB-resin and high light transmittance thermoplastic polyolefin resin, wherein the EVA has the advantages of low costs and high light transmittance and is currently the most used encapsulation material for solar cell module. Besides, there are other technical suggestions of transparent resin, e.g. in the patent US2012260975A1, thermoplastic elastomer resin acrylic is used, wherein the nature of high light transmittance, low haze, no need of UV absorbers, lead to an increased probability of light incidence on the solar cell module, without risk of acetate dissociation due to high temperature and high moisture, thereby ensuring high lifetime of the solar cell module.

However, aging of EVA due to UV and/or heat damage is still a problem. For solving this problem the patents U.S. Pat. No. 6,093,757, WO06093936, IP2000183382, U.S. Pat. No. 7,368,655, EA0001908 and U.S. Pat. No. 5,447,576 disclose several methods, including: adding UV absorbers for increasing UV resistance of transparent resin, adding stabilizers for improving heat resistance of transparent resin and/or adding resin accelerator, like peroxide, to quick hardening transparent resin and avoid generating photoacid. However, while increasing the UV and heat resistance of the transparent resin, thereby the probability of light incidence on the solar cell is reduced, since additives absorb light source of certain wavelengths, therefore the photoelectric conversion efficiency of solar cell is reduced after encapsulation. Looking for low costs and high efficiency, a better encapsulation film is required for improving the efficiency of a solar cell.

### SUMMARY OF THE INVENTION

The main object of the present invention is to provide a composition of an encapsulation film for a solar cell module, comprising 80˜99 weight percent of transparent resin, 0.5˜10 weight percent of granular polymer particles and 0.1˜5 weight percent of additives, wherein light refraction is controlled by a diffusion mechanism of the granular polymer particles, wherein the probability of light incidence on the solar cell is thereby increased, and furthermore the photoelectric conversion efficiency of solar cell is improved. Thereby light refraction is controlled by diffusion mechanism of the granular polymer particles, so that the probability of light incidence on the solar cell is increased, and furthermore the photoelectric conversion efficiency of the solar cell is improved.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1 is an abridged general view of the present invention applied to a solar cell module.

### DESCRIPTION OF THE PREFERRED EMBODIMENTS

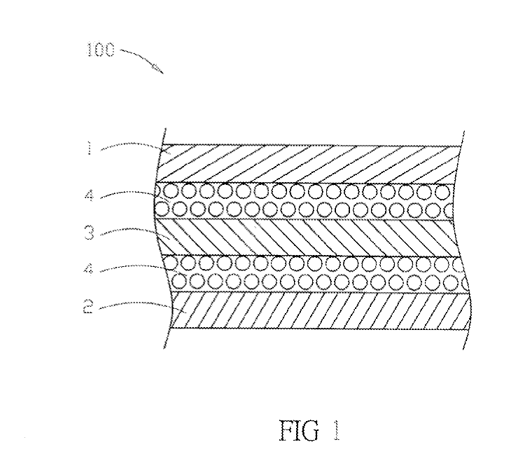

As shown in FIG. 1, a composition of an encapsulation film for a solar cell module of the present invention comprising 80˜99 weight percent of transparent resin, 0.5˜10 weight percent of granular polymer particles and 0.1˜5 weight percent of additives, is applied to a solar cell module 100; as compared to a conventional encapsulation film for a solar cell module, the probability of light incidence on the solar cell in this invention is increased and furthermore the photoelectric conversion efficiency of the solar is improved since light refraction were controlled by the diffusion mechanism due to added granular polymer particles.

FIG. 1 is an abridged general view of the present invention applied to a solar cell module in the sequence of a transparent front plate 1, an encapsulation film 4, a solar cell 3, an encapsulation film 4, a back plate 2. The transparent front plate 1, the back plate 2 and the encapsulation film 4 are used for effective protect encapsulation units, like solar cell 3, and avoiding dissociation due to air and water vapor. The present invention provides the composition of the encapsulation film 4, wherein the probability of light incidence on the solar cell is increased and furthermore the photoelectric conversion efficiency of the solar cell is improved.

Transparent resin is the substitute of the said composition, having the 80˜99 weight percent of the components. One can choose materials of well transmittance and well matte, like. EVA-resin or PVB-resin or transmittance thermoplastic polyolefin resin or thermoplastic elastomer resin acrylic or thermoplastic polyolefin resin of high light transparence. The said EVA-resin is prefer to have 20-40 weight percent of vinyl acetate. The said thermoplastic elastomer resin acrylic consists of polymer of diblock (A-B) or triblock (A-B-A) types, wherein the components are poly(methylmethacrylate-b-isoprene), poly(methylmethacrylate-b-butadiene), poly(methylmethacrylate-b-isoprene-b-methylmethacrylate), poly(methylmethacrylate-b-butadiene-b-methylmethacrylate), poly(methylmethacrylate-b-isoprene/butadiene-b-methylmethacrylate), poly methylmethacrylate blocks and a vinyl bonded rich polyisoprene blocks. The said thermoplastic elastomer resin acrylic has 20-60 weight percent of PMMA, wherein the 30˜50 weight percent is preferred.

The well-mixed granular polymer particles were consist of 0.5-10 total weight percent of transparent resin, and which the granular polymer particles could be acrylic macromolecules. Preferably, the particles consist of polyacrylate resin and derivates co-polymer; wherein the particles are spherical, wherein particle sizes of 30-300 μm are preferred. If the particles size are too large, and then transmittance would decrease, on the other hand, if the particle size gets too small, the improving efficiency is reduced. Besides, the index of refraction is between 1.4-1.55, if the lower refraction index, the light diffusion is inefficient. However, if the higher refraction index, the transmittance is lowed. The said granular polymer particles have well diffusion, are easily to be mixed with the transparent resin, wherein accumulation of particles is limited; The granular particles process mixing with transparent resin directly, without extra process and equipments, thereby the production process is simplified and then costs would saved.

Additives added to the transparent resin as different condition required within and having 0.1˜5 weight percent of the composition, are used for conventional encapsulation film for a solar cell module, which is one or mixture of at least two species of the following: resin accelerator, resin heat stabilizer and UV-absorber, thereby, a high lifetime of the solar cell module is secured and encapsulation processes are improved. Examples are described as follows:

Resin accelerators are peroxide, from one or mixture of at least two species of the following: benzoyl peroxide, dicumyl peroxide, 2,5-dimethyl-2,5-di(tert-butylperoxy)hexane, 1,1-Di-(tert-butylperoxy)-3,3,5-trimethylcyclohexane, heating produced free radical and then causes EVA crosslinked, further causes the thermoplastic transparent resin trans to thermosetting transparent resin. therefore, transparent resin after encapsulation will not change its nature due to heating, and can protect the encapsulation units of the solar cell, avoiding influence from air and water vapour.

Resin thermal stabilizer is one or mixture of at least two species from dibutyl hydroxy-toluene, bis(2,2,6,6-tetramethyl-4-piperidyl) sebacate for stabilize free radical, which generated from breaking bonds of EVA due to the heat or UV-radiation, meanwhile, avoiding further reaction between free radical and EVA-structure, and cutting them into small pieces.

The UV-absorbers are one or mixture of at least two species from benzophenone, benzotriazole, triazine resin and salicylate, wherein the UV-ray is converted to thermal energy, and furthermore the phenomenon of break bonds of EVA due to UV-ray influence is avoided.

For understanding the objects mentioned above, character and advantages of the present invention, preferred. embodiments are explained as follows:

### Embodiment 1

1000 g of EVA-resin (DuPont: D250, VA: 28%) and 30 g of additives are set in a double screw mixer for compounding and granulation, then set with 10 g granular polymer particles (Riken: MX-1000, particle size 10 μm) into the double screw mixer for compounding and granulation and then pressing into film (at this time the light transmittance of the encapsulation film is measured), thereafter, measuring the photoelectric conversion efficiency of a monocrystalline silicon solar cell before encapsulation with a solar simulator is employed. After measuring, as shown in FIG. 1, stacking the structure of an encapsulation film for a solar cell module in sequence of: transparent front plate 1, encapsulation film 4, solar cell 3, encapsulation film 4 and back plate 2; and then set the stacked structure into laminating machine processing for module encapsulation, then measuring photoelectric conversion efficiency of after encapsulation with a solar simulator. The measured values were shown in Table 1.

### 1Embodiment 2

Processing of embodiment 2 is similar to Embodiment 1, the difference therein is using 30 g of granular polymer particles, The before and after encapsulation values measured of the photoelectric conversion efficiency were shown in the Table 1.

### Embodiment 3

1000 g of EVA-resin (DuPont: D250, VA 28%) and 30 g of additives are set in a double screw mixer for compounding and granulation; then with 10 g of granular polymer particles (Riken: MX-3000, particle size 30 μm) are set in the double screw mixer for compounding and granulation and then pressing into a film, thereafter, measuring the photoelectric conversion efficiency of a monocrystalline silicon solar cell before encapsulation with a solar simulator is employed. After measuring, as shown in FIG. 1, stacking the structure of an encapsulation film for a solar cell module in sequence of: transparent front plate 1, encapsulation film 4, solar cell 3, encapsulation film 4 and back plate 2, and then set the stacked structure into laminating machine processing for module encapsulation, then measuring photoelectric conversion efficiency of after encapsulation with a solar simulator. The measured values were shown in Table 1.

### Embodiment 4

Processing by the 4th embodiment is in general the same as in the Embodiment 3, the difference thereto being that 30 g of granular polymer particles are used. The measured values were shown in Table 1.

### Embodiment 5

1000 g of thermoplastic elastomer acrylic resin was taken (Kuraray: LA2140e, PMMA block 20%) and 10 g of granular polymer parades (Riken: MX-1000, particle size of 10 μm) set into a double screw mixer for compounding and granulation and pressing into a film, thereafter, measuring the photoelectric conversion efficiency of a monocrystalline silicon solar cell before encapsulation with a solar simulator is employed. After measuring, as shown in FIG. 1, stacking the structure of an encapsulation film for a solar cell module in sequence of: a transparent front plate 1, encapsulation film 4, solar cell 3, encapsulation film 4 and back plate 2, and then set the stacked structure into laminating machine processing for module encapsulation, then measuring photoelectric conversion efficiency of after encapsulation with a solar simulator. The measured values were shown in Table 1.

### Embodiment 6

Processing by the embodiment 6 is in general the same as by the embodiment 5, the difference is using 30 g of granular macromolecule particles. The before and after measure values of photoelectric conversion efficiency of encapsulation solar cell are shown in Table 1.

### Embodiment 7

1000 g of thermoplastic elastomer acrylic resin (Kuraray: LA2140e, PMMA block 20%) and 10 g of granular polymer particles (Riken: MX-300, particle size 3 μm) are set into a double screw mixer for compounding and granulation, and then pressing into a film, thereafter, measuring the photoelectric conversion efficiency of a polysilicon solar cell before encapsulation with a solar simulator is employed. After measuring, as shown in FIG. 1, stacking the structure of an encapsulation film for a solar cell module in sequence of: a transparent front plate 1, encapsulation film 4, solar cell 3, encapsulation film 4 and back plate 2, and then set the stacked structure into laminating machine processing for module encapsulation, then measuring photoelectric conversion efficiency of after encapsulation with a solar simulator. The measured values were shown in Table 1.

### Embodiment 8

1000 g acrylic resin (Kuraray: LA2140e, PMMA block 20%) and 10 g granular polymer particles (Riken: MX-3000, particle size 30 μm) are taken and placed into a double screw mixer for compounding and granulation, and then pressing into a film, thereafter, measuring the photoelectric conversion efficiency of a polycrystalline silicon solar cell before encapsulation with a solar simulator is employed. After measuring, as shown in FIG. 1, stacking the structure of an encapsulation film for a solar cell module in sequence of: a transparent front plate 1, encapsulation film 4, solar cell 3, encapsulation film 4 and back plate 2, and then set the stacked structure into laminating machine processing for module encapsulation, then measuring photoelectric conversion efficiency of after encapsulation with a solar simulator. The measured values were shown in Table 1.

### Comparative Example 1

Commercial EVA (—Asorbe Purchased from Kuo Hsin technologic company: KhtcEVA) is taken for efficiency measuring before and after encapsulation. As shown in Table 1.

### Comparative Example 2

A commercial thermoplastic elastomer acrylic resin is taken (Kuraray: LA2140e, PMMA block 20%) for efficiency measuring before and after encapsulation, as shown in Table 1.

TABLE 1

| | Photoelectric | Photoelectric | | |
|---|---|---|---|---|
| | conversion | conversion | | |
| | efficiency | efficiency | | |
| | before | after | Efficiency | Photo- |
| | encapsulation | encapsulation | increasing | electric |
| | (Watt) | (Watt) | (%) | rate (%) |
| Embodiment 1 | 4.14 | 4.19 | 1.32 | 89.11 |
| Embodiment 2 | 4.12 | 4.21 | 2.05 | 89.15 |
| Embodiment 3 | 4.14 | 4.21 | 1.62 | 88.77 |
| Embodiment 4 | 4.11 | 4.18 | 1.86 | 88.37 |
| Embodiment 5 | 3.99 | 4.08 | 2.21 | 86.60 |
| Embodiment 6 | 4.01 | 4.09 | 1.99 | 86.55 |
| Embodiment 7 | 3.12 | 3.24 | 3.60 | 87.89 |
| Embodiment 8 | 3.08 | 3.20 | 3.81 | 88.83 |
| Comparative | 4.06 | 4.03 | −0.74 | 89.21 |
| Example 1 | | | | |
| Comparative | 4 | 4.03 | 0.66 | 91 |
| Example 2 | | | | |

As shown in Table 1, conventional EVA-resin is used in a comparative example 1 as an encapsulation film for protecting encapsulation solar cell unit, but photoelectric conversion efficiency is decreased to the module, which was caused by additives absorbed of some specific wavelength of light resources when after encapsulation processed. Since the comparative example 2 without adding UV absorber, the photoelectric conversion efficiency is not decrease. However, not only the embodiments 1-8 of the present invention added granular polymer particles into encapsulation material, but also the photoelectric conversion efficiency of the solar cell module after encapsulation is comparatively increased, therefore, the generated electrical energy of the solar cell module after encapsulation is definitely improved.

While preferred embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

1. A composition of an encapsulation film for a solar cell module, comprising:
80˜99 total weight percent of transparent resin,
0.5˜10 total weight percent of granular polymer particles and
0.1˜5 total weight percent of additives.

2. The composition of an encapsulation film for a solar cell module of claim 1, wherein the transparent resin is EVA-resin or thermoplastic elastomer resin acrylic or PVB-resin or high light transmittance thermoplastic polyolefin resin.

3. The composition of an encapsulation film for a solar cell module of claim 2, wherein the EVA-resin has 20-40 weight percent of vinyl acetate.

4. The composition of an encapsulation film for a solar cell module of claim 2, wherein the thermoplastic elastomer resin acrylic consists of a diblock (A-B) type or triblock (A-B-A) types of copolymers; the components thereof are poly(methylmethacrylate-b-isoprene), poly(methylmethacrylate-b-butadiene), poly(methylmethacrylate-b-butadiene), poly(methylmethacrylate-b-isoprene-b-methylmethacrylate), poly(methylmethacrylate-b-butadiene-b-methylmethacrylate), poly(methylmethacrylate-b-isoprene/butadiene-b-methylmethacrylate), poly methylmethacrylate blocks and a vinyl bonded rich polyisoprene block.

5. The composition of an encapsulation film for a solar cell module of claim 4, wherein the thermoplastic elastomer resin acrylic have 30-50 weight percent of PMMA.

6. The composition of an encapsulation film for a solar cell module of claim 1, wherein the granular polymer particles are acrylic polymer.

7. The composition of an encapsulation film for a solar cell module of claim 6, wherein the acrylic polymer consists of polyacrylate resin and derivative copolymer.

8. The composition of an encapsulation film for a solar cell module of claim 6, wherein the granular polymer particles are sphere shape polymer with particle sizes of 3˜300 μm.

9. The composition of an encapsulation film for a solar cell module of claim 6, wherein the index of refraction of the granular polymer particles is between 1.4˜1.55.

10. The composition of an encapsulation film for a solar cell module of claim 1, wherein the additives are one or mixture of at least two items of the following: resin accelerator, resin heat stabilizer and UV-absorber.

11. The composition of an encapsulation film for a solar cell module of claim 10, wherein the resin accelerator is peroxide.

12. The composition of an encapsulation film for a solar cell module of claim 11, wherein the resin accelerators are one or mixture of at least two items of the following: benzoyl peroxide, dicumyl peroxide, 2,5-dimethyl-2,5-di(tert-butylperoxy)hexane and 1,1-Di-(tert-butylperoxy)-3,3,5-trimethylcyclohexane.

13. The composition of an encapsulation film for a solar cell module of claim 10, wherein the resin heat stabilizers are one or mixture of at least two items of the following: dibutyl hydroxy-toluene, sebacic acid and bis(2,2,6,6-tetramethyl-4-piperidyl).

14. The composition of an encapsulation film for a solar cell module of claim 10, wherein the UV-absorber is one or mixture of at least two items of the following: benzophenone, triazolyl and salicylate.
